(19) United States
(12) Patent Application Publication
(10) Pub. No.: US 2006/0148213 A1
(43) Pub. Date: Jul. 6, 2006

(54) Method of manufacturing display device

(76) Inventors: Fumitoshi Iwamura, Fukaya-shi (JP); Yasushi Okamoto, Fukaya-shi (JP); Hiroki Oonishi, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/366,398

(22) Filed: Mar. 3, 2006

Related U.S. Application Data
(63) Continuation of application No. PCT/JP04/12567, filed on Aug. 31, 2004.

(30) Foreign Application Priority Data
Sep. 5, 2003 (JP) 2003-314166

(51) Int. Cl. H01L 21/78; H01L 21/301

(52) U.S. Cl. 438/463; 219/121.72

(57) ABSTRACT

Y-scribe lines are successively formed substantially in parallel in a first direction of a work that constitutes a display device. An X-scribe line is formed in a second direction that intersects the first direction of the work. The X-scribe line is formed between the Y-scribe lines and is spaced apart from the Y-scribe lines.

### CROSS REFERENCE TO RELATED APPLICATIONS

This is a Continuation Application of PCT Application No. PCT/JP2004/012567, filed Aug. 31, 2004, which was published under PCT Article 21(2) in Japanese.

This application is based upon and claims the benefit of priority from prior Japanese Patent Application No. 2003-314166, filed Sep. 5, 2003, the entire contents of which are incorporated herein by reference.

### BACKGROUND OF THE INVENTION

1. Field of the Invention

The present invention relates to a method of manufacturing a display device, and more particularly to a method of cutting, or dicing, a display device with a predetermined size out of a glass base material.

2. Description of the Related Art

A liquid crystal display device, which is an example of the display device, is configured such that a liquid crystal layer is interposed between a pair of substrates. For higher efficiency of fabrication, such display devices are, in usual cases, individually cut out of a large-sized glass base material on which a plurality of display units are formed in advance. In particular, small-sized display devices for mobile equipment can easily be mass-produced by this method.

In the above fabrication method, for example, a glass base material is linearly scribed in a short-side direction (X direction), following which the glass base material is linearly scribed in a long-side direction (Y direction). Then, the glass base material is cut, or diced, into predetermined sizes (see, e.g. Jpn. Pat. Appln. KOKAI Publication No. 2002-182180).

In order to cut out a rectangular display device, an X-scribe line, which is first formed by scribing in the X direction, is crossed with a Y-scribe line, which is subsequently formed by scribing in the Y direction, at an area corresponding to corner parts of the display device.

In this case, when the subsequently formed Y-scribe line crosses the previously formed X-scribe line, an excessive stress acts in the glass base material and the glass base material may partly be chipped. A display device, which is cut out with such a chip, is regarded as a defective one. Consequently, the manufacturing yield lowers and the manufacturing cost increases.

### BRIEF SUMMARY OF THE INVENTION

The present invention has been made in consideration of the above-described problem, and the object of the object of the invention is to provide a method of manufacturing a display device, which is capable of suppressing occurrence of a defective product, and achieving an increase in manufacturing yield and a decrease in manufacturing cost.

According to a first aspect of the present invention, there is provided a method of manufacturing a display device comprising:

a step of forming a first scribe line in a first direction of an insulating substrate that forms the display device; and

a step of forming a second scribe line in a second direction that intersects the first direction of the insulating substrate,

wherein the second scribe line is formed such that the second scribe line is spaced apart from the first scribe line that is formed in the preceding step.

According to a second aspect of the present invention, there is provided a method of manufacturing a display device comprising:

a step of forming an effective display section, which forms the display device, on an insulating substrate;

a step of successively forming a first scribe line and a third scribe line substantially in parallel in a first direction of the insulating substrate such that the effective display section is sandwiched between the first scribe line and the third scribe line; and

a step of successively forming a second scribe line and a fourth scribe line in a second direction, which is substantially perpendicular to the first direction of the insulating substrate, such that the effective display section is sandwiched between the second scribe line and the fourth scribe line,

wherein the second scribe line and the fourth scribe line are formed between the first scribe line and the third scribe line that are formed in the preceding step, and are spaced apart from the first scribe line and the third scribe line.

According to a third aspect of the present invention, there is provided a method of manufacturing a display device, wherein an insulating substrate that forms the display device is scribed, the method comprising:

a step of lowering a scribe member, pressing the scribe member on a first start point on the insulating substrate under a predetermined load, and scribing the insulating substrate from the first start point to a first end point in a first direction, thereby forming a first scribe line; and

a step of lowering the scribe member, pressing the scribe member on a second start point, which is spaced apart from the first scribe line, under a predetermined load, and scribing the insulating substrate from the second start point to a second end point in a second direction that intersects the first direction, thereby forming a second scribe line that is spaced apart from the first scribe line.

According to a fourth aspect of the present invention, there is provided a method of manufacturing a display device comprising:

a step of forming an effective display section, which forms the display device, on an insulating substrate; and

a step of forming a scribe line in a direction that intersects an edge of the insulating substrate,

wherein the effective display section has one side that agrees with the edge of the insulating substrate, and

the scribe line is spaced apart from the edge of the insulating substrate.

### BRIEF DESCRIPTION OF THE SEVERAL VIEWS OF THE DRAWING

FIG. 1 schematically shows the structure of a liquid crystal display device according to an embodiment of the present invention;

FIG. 2 is a view for explaining a method of manufacturing the liquid crystal display panel;

FIG. 3 is a view for explaining the method of manufacturing the liquid crystal display panel;

FIG. 4 is a view for explaining the method of manufacturing the liquid crystal display panel;

FIG. 5 is a view for explaining the method of manufacturing the liquid crystal display panel;

FIG. 6 is a view for explaining the method of manufacturing the liquid crystal display panel;

FIG. 7 schematically shows the structure of an apparatus for dicing a plurality of liquid crystal display panels from a large-sized substrate;

FIG. 8 is a view for explaining the positional relationship between scribe lines, which are formed on a work, and start and end points thereof;

FIG. 9 is a view for explaining margins between previously formed scribe lines and the start and end points of a subsequently formed scribe line;

FIG. 10A shows the shape of a corner portion of a liquid crystal display panel that is fabricated by the manufacturing method of the present embodiment;

FIG. 10B shows the shape of a corner portion of a liquid crystal display panel that is fabricated by a prior-art manufacturing method; and

FIG. 11 is a view for explaining the positional relationship between scribe lines that are formed on a work according to another embodiment of the invention.

### DETAILED DESCRIPTION OF THE INVENTION

A method of manufacturing a display device according to an embodiment of the present invention will now be described with reference to the accompanying drawings. In this embodiment, a liquid crystal display device is described as an example of the display device.

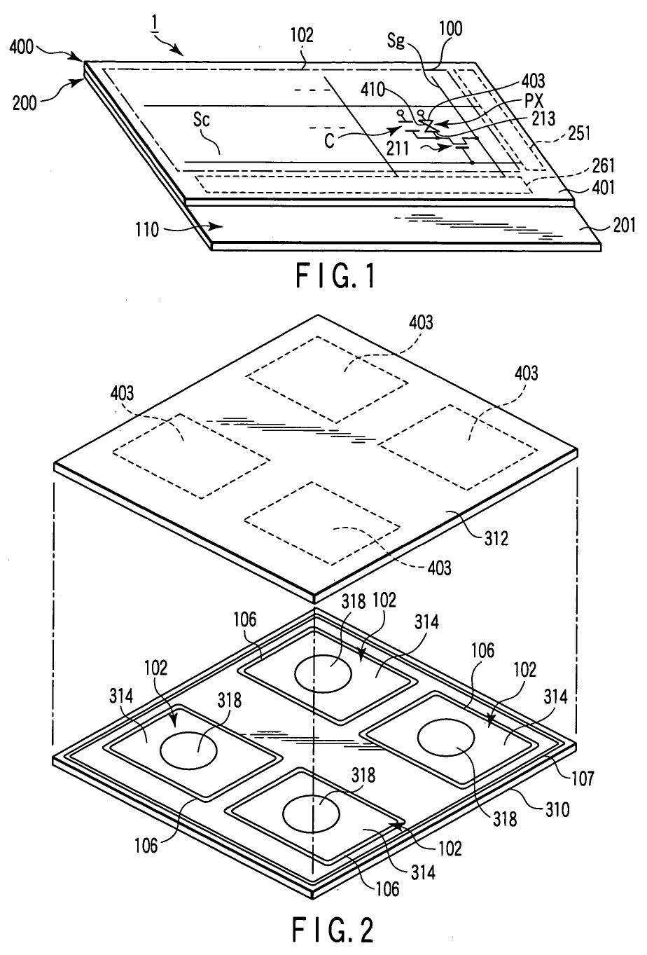

As is shown in FIG. 1, a liquid crystal display apparatus 1 comprises a liquid crystal panel 100. The liquid crystal panel 100 has an effective display section 102 for displaying an image. The effective display section 102 includes a plurality of display pixels PX arranged in a matrix. The liquid crystal panel 100 includes an array substrate 200, a counter electrode 400, and a liquid crystal layer 410 that is held between the array substrate 200 and counter substrate 400.

In the liquid crystal display panel 100, the array substrate 200 is formed using a light-transmissive insulation substrate 201, for instance, a glass substrate 201. In the effective display section 102, the array substrate 200 includes, on one of major surfaces (i.e. front surface) of the glass substrate 201, a plurality of signal lines Sg and a plurality of scan lines Sc arranged in a matrix, switch elements 211 disposed near intersections of the signal lines Sg and scan lines Sc, and pixel electrodes 213 connected to the switch elements 211.

The switch element 211 comprises a thin film transistor (TFT) that includes, e.g. a polysilicon film as an active layer. The switching element 211 has a gate electrode connected to the scan line Sc, a source electrode connected to the pixel electrode 213, and a drain electrode connected to the signal line Sg.

The counter substrate 400 is formed using a light-transmissive insulation substrate 401, for instance, a glass substrate 401. In the effective display section 102, the counter substrate 400 includes, on one of major surfaces (i.e. front surface) of the insulation substrate 401, a counter electrode 403 that is disposed to face the pixel electrode 213.

The array substrate 200 and counter substrate 400 are bonded to each other with a predetermined gap, which is provided by, e.g. a columnar spacer that is disposed at least within the effective display section 102. The liquid crystal layer 410 is formed of a liquid crystal composition that is sealed in the predetermined gap of the liquid crystal display panel 100.

The liquid crystal display panel 100 includes a drive circuit section 110 that is disposed on a peripheral area of the effective display section 102. The drive circuit section 110 includes at least a part of a scan line drive section 251, which is disposed on one end side of the scan lines Sc, and a part of a signal line drive section 261, which is disposed on one end side of the signal lines Sg. The scan line drive section 251 supplies drive signals (scan pulses) to the scan lines Sc. The signal line drive section 261 supplies drive signals to the signal lines Sg. The scan line drive section 251 and signal line drive section 261, like the switching element 211 within the effective display section 102, thin-film transistors each including a polysilicon film.

Further, in the liquid crystal display panel 100, polarizer plates are disposed, where necessary, on the outer surface of the array substrate 200 and the outer surface of the counter substrate 400, in accordance with characteristics of the liquid crystal layer 410.

A method of manufacturing the liquid crystal panel in the liquid crystal display apparatus with the above-described structure will now be described. In addition, a method of dicing a plurality of liquid crystal display panels from a large-sized base material is described.

As is shown in FIG. 2 and FIG. 3, a first glass base material 310 and a second glass base material 312, each having a thickness of about 0.7 mm, are prepared. The first glass base material 310 and second glass base material 312 are formed with such a size that four liquid crystal panels, for instance, can be formed.

A display device section 314 including a switch element formed by using a low-temperature polysilicon film as an active layer, a pixel electrode formed by using a metallic material such as ITO (indium tin oxide) or aluminum, a color filter, an orientation film, etc. is formed in each of four effective display regions 102 provided on the first glass base material 310. The respective drive sections are formed on the drive circuit section 110 that is provided on a peripheral part of each effective display section 102. In addition, a connection electrode section 316 for connecting the respective drive sections and the display device region 314 is formed.

Subsequently, a seal material 106 is coated in a frame-like shape around each effective display section 102. Further, a dummy seal 107 is coated along an entire peripheral portion on the first glass base material 310. The seal material 106 and dummy seal 107 are formed of an adhesive such as a thermosetting adhesive or a light (e.g. ultraviolet) curing adhesive. In this example, the seal material 106 and dummy seal 107 are applied by a dispenser using, e.g. an epoxy adhesive. The connection electrode section 316 extends to the outside of the seal material 106.

On the other hand, a counter electrode 403 formed of a light-transmissive metallic material such as ITO, an orientation film, etc. are formed at four areas on the second glass base material 312 in association with the effective display sections 102.

A predetermined amount of liquid crystal material 318 is dropped on each region surrounded by each seal material 106 on the first glass base material 310. Then, the first glass base material 310 and second glass base material 312 are positioned such that each display device circuit section 314 on the first glass base material 310 faces the associated counter electrode 403 on the second glass base material 312.

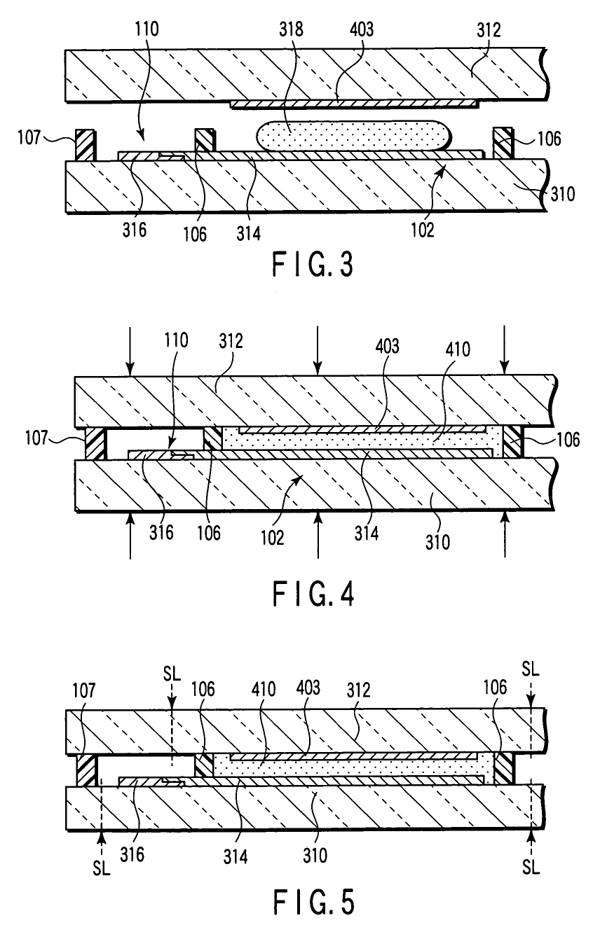

Thereafter, as shown in FIG. 4, the first glass base material 310 and second glass base material 312 are pressed under a predetermined pressure in directions toward each other. Further, the seal material 106 and dummy seal 107 are cured and the first glass base material 310 and second glass base material 312 are attached to each other. Thus, the first glass base material 310 and second glass base material 312 are attached to each other by the seal material 106 and dummy seal 107, and the liquid crystal layer 410 is formed between the first glass base material 310 and second glass base material 312 in each effective display section 102.

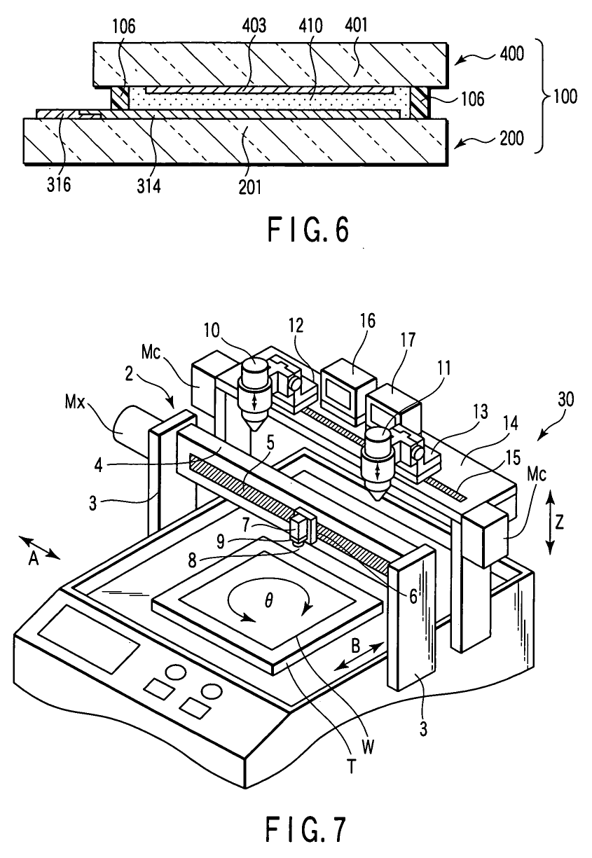

Then, as shown in FIG. 5, the first glass base material 310 and second glass base material 312 are diced along scribe lines SL at predetermined positions into four sections, and a liquid crystal display panel 100 as shown in FIG. 6 is cut out. The dicing process is described later in detail. Where necessary, polarizer plates are provided on the outer surface of the glass substrate 201 and the outer surface of the glass substrate 401. Through the above-described steps, the liquid crystal display panel is completed.

In the above-described manufacturing method of the liquid crystal display panel, it is possible to decrease the time for manufacture by dropping the liquid crystal material 318 on one of the substrates before the substrates are bonded, and thus forming the liquid crystal layer 410. Alternatively, after an empty liquid crystal cell is formed, a liquid crystal material may be vacuum-injected in the cell.

The process of dicing a plurality of liquid crystal display panels 100 from a pair of glass base materials 310 and 312 is described. To begin with, an apparatus for dicing the glass base materials is described.

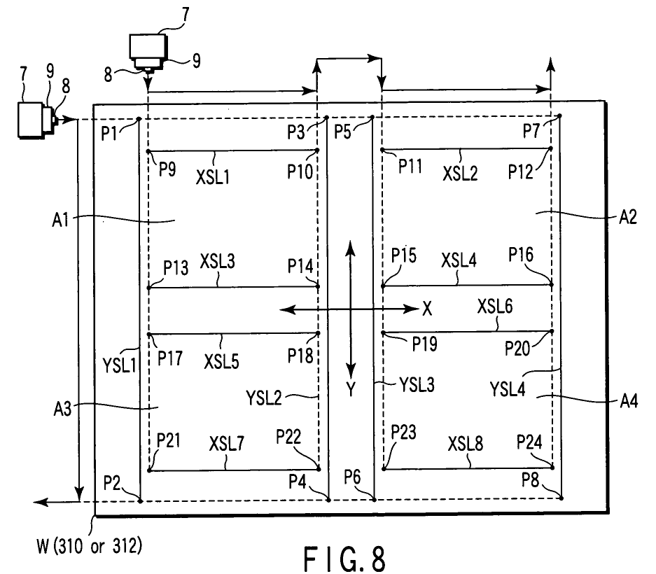

As is shown in FIG. 7, a glass cutting apparatus 30 that scribes the glass base material comprises a table T, a bridge 2, a scribe head 7, cameras 10 and 11, and monitors 16 and 17.

The table T has a table surface on which a work W is placeable. The work W is a pair of glass base materials 310 and 312 that are bonded to each other in the state in which the liquid crystal layer 410 is held therebetween, as shown in FIG. 4. The table T fixes the work W, which is placed on the table surface, by suction. The table T is configured to be movable in a direction of a double-headed arrow B, and is rotatable by 90° or more in a θ direction within the plane of the table surface.

The bridge 2 is so disposed as to straddle the table T. The bridge 2 comprises a pair of support columns 3, which are disposed on both sides of the table T, and a guide bar 4, which extends in a direction of a double-headed arrow A and is supported on the support columns 3.

The scribe head 7 is provided on a holder support 6. The holder support 6 is configured to be movable in the direction of arrow A along a guide 5 that is formed on the guide bar 4. The holder support 6 is driven in the direction of arrow A by means of a motor Mx. In addition, the holder support 6 is configured to vertically drive the scribe head 7 in a direction of a double-headed arrow Z. The scribe head 7 includes, at its lower part, that is, at its part facing the table T, a chip holder 9 that rotatably holds a sawtooth cutter wheel chip (scribe member) 8.

The cameras 10 and 11 capture an image of the work W, and read alignment marks that are formed on the work W in advance. The cameras 10 and 11 are provided on seats 12 and 13, respectively, which are movable in the directions of arrows A and B. The seats 12 and 13 are individually driven along a guide 15, which is provided on a support 14 extending in the direction of arrow A, by means of motors MC. The cameras 10 and 11 are configured to be movable in the direction of arrow Z for focus adjustment. The monitors 16 and 17 display images that are acquired by the cameras 10 and 11.

The glass cutting apparatus 30 with the above-described structure operates, as will be described below, and scribes the glass base materials. For the purpose of simple description, assume that the work W, as shown in FIG. 8, has four regions corresponding to liquid crystal display panels on a large-sized glass base material.

To start with, the work W is set on the table T. If the glass cutting apparatus 30 is operated, the work W is sucked and fixed on the table surface. Then, the work W is imaged by the cameras 10 and 11. Thus, the alignment marks, which are formed on the work W in advance, are read, and a positional displacement at the time of setting the work W is detected. The table T rotates in the θ direction on the basis of the detected positional displacement, thus correcting the positional displacement.

Subsequently, the table T further rotates in the θ direction by 90°. Thereby, the Y-direction (e.g. direction of extension of scan lines Sc) of the work W is set to be parallel to the direction A of movement of the holder support 6, and the X-direction (e.g. direction of extension of signal lines Sg) of the work W is set to be parallel to the direction B of movement of the table T.

Thereafter, the cutter wheel chip 8 is aligned with a first point P1. At this time, for example, the table T moves in the direction of arrow B and the holder support 6 moves in the direction of arrow A so that the first point P1 on the work W may be aligned with the cutter wheel chip 8. After the cutter wheel chip 8 has been aligned with the first point P1, the scribe head 7 is lowered in the direction Z and the cutter wheel chip 8 is pressed on the first point P1 under a predetermined load.

While the table T is maintained in the fixed state, the holder support 6 is moved in the direction of arrow A along the guide 5 of guide bar 4 by the driving of the motor Mx. With the movement of the holder support 6, the cutter wheel chip 8 is moved from the first point P1 on the work W to a second point P2. The work W is thus scribed. Thereby, a Y-scribe line YSL1, which extends from the first point P1 that is the start point to the second point P2 that is the end point, is formed.

At the second point P2, the scribe head 7 is moved upward in the direction Z and the cutter wheel chip 8 is separated from the work W. Then, with movements of the holder support 6 and table T, the cutter wheel chip 8 is aligned with a third point P3. In other words, the cutter wheel chip 8 is moved to the start point of a scribe line by relative movements of the work W by means of the table T and the holder support 6 that holds the cutter wheel chip 8.

Similarly, a Y-scribe line YSL2, which extends from the third point P3 that is the start point to a fourth point P4 that is the end point, is formed. Further, a Y-scribe line YSL3, which extends from a fifth point P5 that is the start point to a sixth point P6 that is the end point, and a Y-scribe line YSL4, which extends from a seventh point P7 that is the start point to an eighth point P8 that is the end point, are successively formed.

At the eighth point P8, the scribe head 7 is moved upward in the direction Z and the cutter wheel chip 8 is separated from the work W. Then, the table T rotates in the θ direction by 90°. Thereby, the Y-direction of the work W is set to be parallel to the direction B of movement of the table T, and the X-direction of the work W is set to be parallel to the direction A of movement of the holder support 6.

Then, with movements of the holder support 6 and table T, the cutter wheel chip 8 is aligned with a ninth point P9. After the cutter wheel chip 8 has been aligned with the ninth point P9, the scribe head 7 is lowered in the direction Z and the cutter wheel chip 8 is pressed on the ninth point P9 under a predetermined load.

While the table T is maintained in the fixed state, the holder support 6 is moved in the direction of arrow A along the guide 5 of guide bar 4 by the driving of the motor Mx. With the movement of the holder support 6, the cutter wheel chip 8 is moved from the ninth point P9 on the work W to a tenth point P10. The work W is thus scribed. Thereby, an X-scribe line XSL1, which extends from the ninth point P9 that is the start point to the tenth point P10 that is the end point, is formed.

The ninth point P9 is a point that is apart from each of the Y-scribe lines YSL1 to YSL4. The tenth point P10 is a point that is also apart from each of the Y-scribe lines YSL1 to YSL4. In addition, the ninth point P9 and tenth point P10 are present between two adjacent Y-scribe lines YSL1 and YSL2.

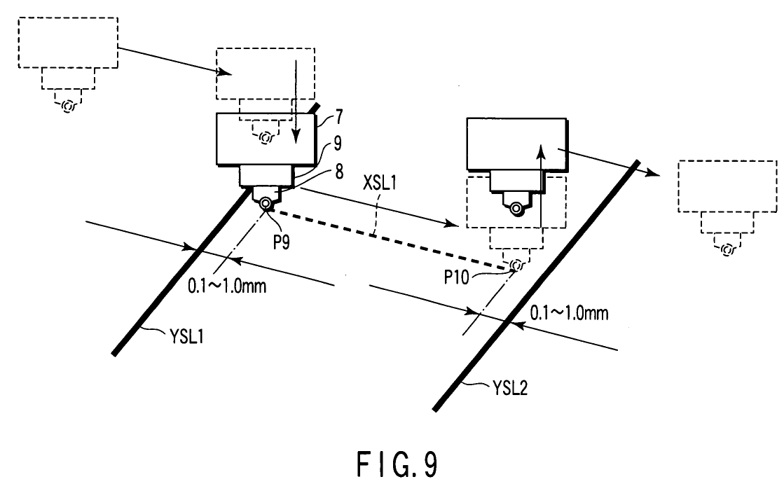

For example, as shown in FIG. 9, the ninth point P9 is present between the Y-scribe lines YSL1 and YSL2, and the shortest distance between the ninth point P9 and the Y-scribe line YSL1 is between 0.1 mm and 1.0 mm. In addition, the tenth point P10 is present between the Y-scribe lines YSL1 and YSL2, and the shortest distance between the tenth point P10 and the Y-scribe line YSL2 is between 0.1 mm and 1.0 mm. Accordingly, the X-scribe line XSL1 is spaced apart from each of the Y-scribe lines YSL1 to YSL4 and intersects none of the Y-scribe lines YSL1 to YSL4.

At the tenth point P10, the scribe head 7 is moved upward in the direction Z and the cutter wheel chip 8 is separated from the work W. Then, the holder support 6 is moved beyond the Y-scribe lines YSL2 and YSL3. Further, with movement of the holder support 6, the cutter wheel chip 8 is aligned with an eleventh point P11 that is collinear with the X-scribe line XSL1. Similarly, an X-scribe line XSL2, which extends from the eleventh point P11 that is the start point to a twelfth point P12 that is the end point, is formed Each of the eleventh point P11 and twelfth point P12 is a point that is apart from each of the Y-scribe lines YSL1 to YSL4. In addition, each of the eleventh point P11 and twelfth point P12 is present between two adjacent Y-scribe lines YSL3 and YSL4. Accordingly, the X-scribe line XSL2 is spaced apart from each of the Y-scribe lines YSL1 to YSL4 and intersects none of the Y-scribe lines YSL1 to YSL4.

At the twelfth point P12, the scribe head 7 is moved upward in the direction Z and the cutter wheel chip 8 is separated from the work W. Then, the holder support 6 is moved beyond the Y-scribe lines YSL2 and YSL3. Further, with movement of the holder support 6, the cutter wheel chip 8 is aligned with a 13th point P13 that is not collinear with the X-scribe line XSL1. Similarly, an X-scribe line XSL3, which extends from the 13th point P13 that is the start point to a 14th point P14 that is the end point, is formed.

Further, an X-scribe line XSL4, which extends from a 15th point P15 that is the start point to a 16th point P16 that is the end point, is formed. An X-scribe line XSL5, which extends from a 17th point P17 that is the start point to an 18th point P18 that is the end point, is formed. An X-scribe line XSL6, which extends from a 19th point P19 that is the start point to a 20th point P20 that is the end point, is formed. An X-scribe line XSL7, which extends from a 21st point P21 that is the start point to a 22nd point P22 that is the end point, is formed, and an X-scribe line XSL8, which extends from a 23rd point P23 that is the start point to a 24th point P24 that is the end point, is formed.

Thus, the scribing process for one of the glass base materials, which constitute the work W, is completed. The previously formed Y-scribe lines YSL1 to YSL4 intersect none of the subsequently formed X-scribe lines XSL1 to XSL8. However, when an X-scribe line is to be formed and the cutter wheel chip 8 is pressed on the start point of the X-scribe line under a predetermined pressure, which start point is spaced apart from the closest Y-scribe line by 0.1 mm to 1.0 mm, a linear crack runs from the start point toward the closest Y-scribe line. The crack that forms at this time runs collinear with the X-scribe line.

In addition, when the end point of the formed X-scribe line is set at 0.1 mm to 1.0 mm from the closest Y-scribe line, a linear crack runs from the end point toward the closest Y-scribe line. The crack that forms at this time also runs collinear with the X-scribe line.

In a case where the shortest distance between the start point of the X-scribe line and the closest Y-scribe line and between the end point of the X-scribe line and the closest Y-scribe line is set to be less than 0.1 mm, an excessive stress due to the cutter wheel chip 8 acts in the vicinity of a crossing point between the X-scribe line and Y-scribe line, and a chip tends to be occur in the work W, as in the prior art in which the scribe lines are formed to intersect each other.

On the other hand, in a case where the shortest distance between the start point of the X-scribe line and the closest Y-scribe line and between the end point of the X-scribe line and the closest Y-scribe line is set to be greater than 1.0 mm, the direction of run of the crack is not uniformly determined and a specified outer size cannot be obtained, leading to another factor of defects. Therefore, it is desirable that the shortest distance between the start point of the X-scribe line and the closest Y-scribe line and between the end point of the X-scribe line and the closest Y-scribe line be set between 0.1 mm and 1.0 mm.

When an X-scribe line, which intersects neither of the previously formed two neighboring Y-scribe lines, is to be formed between the two neighboring Y-scribe lines, the cutter wheel chip 8 is merely pressed on the start point of the X-scribe line under a predetermined load. However, at the end point of the X-scribe line, a stress due to movement of the holder support 6 acts in addition to the predetermined load due to the cutter wheel chip 8.

Thus, the distance between the end point of the X-scribe line and the closest Y-scribe line may be greater than the distance between the start point of the X-scribe line and the closest Y-scribe line. In other words, it is preferable to set the distance between the start point of the X-scribe line and the closest Y-scribe line to be equal to or less than the distance between the end point of the X-scribe line and the closest Y-scribe line.

As has been described above, although the Y-scribe lines YSL1 to YSL4 intersect none of the X-scribe lines XSL1 to XSL8, regions A1 to A4 that are surrounded by these scribe lines can be cut out.

Following the scribing process for one of the glass base materials of the work W, the work W is reversed and re-set on the table surface, and a similar scribing process is performed. If the scribing processes for both glass materials are completed, the regions A1 to A4 are diced out of the work W and liquid crystal display panels 100 are taken out.

Specifically, the region A1, which is surrounded by the Y-scribe lines YSL1 and YSL2 and X-scribe lines XSL1 and XSL3, the region A2, which is surrounded by the Y-scribe lines YSL3 and YSL4 and X-scribe lines XSL2 and XSL4, the region A3, which is surrounded by the Y-scribe lines YSL1 and YSL2 and X-scribe lines XSL5 and XSL7, and the region A4, which is surrounded by the Y-scribe lines YSL3 and YSL4 and X-scribe lines XSL6 and XSL8, are diced. Thus, the dicing process is completed.

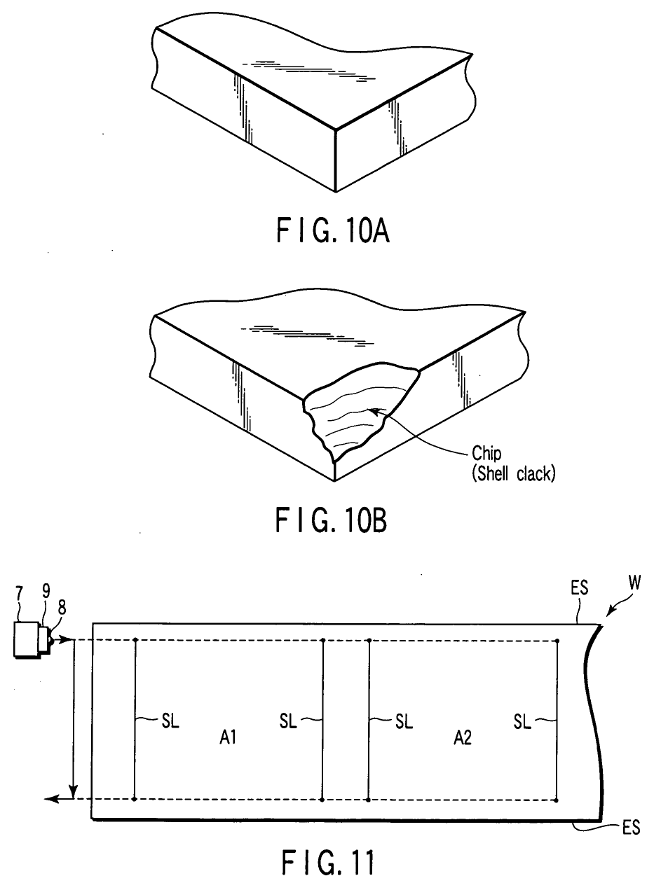

As is shown in FIG. 10A, no chip occurs at the corner portion of the liquid crystal display panel 100 that is diced along the scribe lines that do not interest in the X-direction and Y-direction, and this corner portion has a good shape. By contrast, as shown in FIG. 10B, a chip (shell crack) having a shell-like cross section occurs at a corner portion of a liquid crystal display panel that is diced along scribe lines that interest in the X-direction and Y-direction.

As has been described above, in the case where a plurality of effective display sections 102 are to be cut out of the work W, a plurality of scribe lines are formed on the work W. At this time, X-scribe lines XSL1 and XSL3 that are formed subsequently are present between the previously formed neighboring Y-scribe lines YSL1 and YSL2 and are spaced apart from the Y-scribe lines YSL1 and YSL2.

As is shown in FIG. 8, after the Y-scribe lines YSL1 and YSL2 are successively formed in the first direction Y of the work W so as to sandwich the effective display section (e.g. region A1), X-scribe lines XSL1 and XSL3 are successively formed in the second direction X of the work W, which is perpendicular to the first direction Y, so as to sandwich the effective display section A1.

When X-scribe lines XSL1 and XSL3 are to be formed subsequently, the X-scribe lines XSL1 and XSL3 that are formed do not interest the previously formed Y-scribe lines YSL1 and YSL2. Thus, no chip occurs at the corner portion of the liquid crystal display device 100 that includes the diced effective display section A1.

Thus, the liquid crystal display panel 100 with a predetermined size can surely be obtained, and it is possible to prevent a chip from occurring at the corner portion of the substrate of the liquid crystal display panel 100. Therefore, the occurrence of a defect due to a chip at the corner portion can be suppressed, the manufacturing yield can be increased, and the manufacturing cost can be reduced.

The present invention is not limited to the above-described embodiments. At the stage of practicing the invention, various embodiments may be made by modifying the structural elements without departing from the spirit of the invention. Structural elements disclosed in the embodiments may properly be combined, and various inventions may be made. For example, some structural elements may be omitted from the embodiments. Moreover, structural elements in different embodiments may properly be combined.

For example, in the above-described embodiment, scribe lines are first formed in the Y-direction of the work W, and then scribe lines are formed in the X-direction. Alternatively, scribe lines may first be formed in the X-direction, following which scribe lines may be formed in the Y-direction.

In the embodiment, the liquid crystal display device has been described as the example of the display device. Needless to say, the above-described manufacturing method is applicable to other display devices such as an organic electroluminescent display device.

In the above-described embodiment, emphasis has been placed on the feature that the X-scribe line and the Y-scribe line do not interest each other. However, as shown in FIG. 11, in a case where an edge of a glass base material is used as one side of an effective display section, that is, in a case where a liquid crystal display panel is diced out of a work W that is configured such that regions A1, A2, . . . , which correspond to a plurality of effective display sections, are formed in line in a strip-like glass base material, it should suffice if scribe lines SL are formed only in a direction perpendicular to the edge ES. In the example shown in FIG. 11, two edges ES of the work W correspond to two sides of the effective display section. Thus, there is no need to form scribe lines SL at the four sides, and scribe scribes SL are formed only at the two sides perpendicular to the edges ES. In this case, the scribe lines SL are formed so as to be spaced apart from the edges ES. Thereby, the same advantages as in the above-described embodiment can be obtained.

As has been described above, the present invention can provide a method of manufacturing a display device, which is capable of suppressing occurrence of a defective product, and achieving an increase in manufacturing yield and a decrease in manufacturing cost.

What is claimed is:

1. A method of manufacturing a display device comprising:
a step of forming a first scribe line in a first direction of an insulating substrate that forms the display device; and
a step of forming a second scribe line in a second direction that intersects the first direction of the insulating substrate,
wherein the second scribe line is formed such that the second scribe line is spaced apart from the first scribe line that is formed in the preceding step.

2. The method of manufacturing a display device, according to claim 1, wherein the step of forming the first scribe line includes a step of forming a third scribe line that is parallel to the first scribe line, and
the second scribe line is formed such that the second scribe line is spaced apart from the third scribe line that is formed in the preceding step.

3. The method of manufacturing a display device, according to claim 2, wherein the second scribe line has a start point on the first scribe line side and has an end point on the third scribe line side, and
each of a shortest distance between the start point of the second scribe line and the first scribe line and a shortest distance between the end point of the second scribe line and the third scribe line is between 0.1 mm and 1.0 mm.

4. The method of manufacturing a display device, according to claim 2, wherein the second scribe line has a start point on the first scribe line side and has an end point on the third scribe line side, and
a shortest distance between the start point of the second scribe line and the first scribe line is equal to or less than a shortest distance between the end point of the second scribe line and the third scribe line.

5. A method of manufacturing a display device comprising:
a step of forming an effective display section, which forms the display device, on an insulating substrate;
a step of successively forming a first scribe line and a third scribe line substantially in parallel in a first direction of the insulating substrate such that the effective display section is sandwiched between the first scribe line and the third scribe line; and
a step of successively forming a second scribe line and a fourth scribe line in a second direction, which is substantially perpendicular to the first direction of the insulating substrate, such that the effective display section is sandwiched between the second scribe line and the fourth scribe line,
wherein the second scribe line and the fourth scribe line are formed between the first scribe line and the third scribe line that are formed in the preceding step, and are spaced apart from the first scribe line and the third scribe line.

6. A method of manufacturing a display device, wherein an insulating substrate that forms the display device is scribed, the method comprising:
a step of lowering a scribe member, pressing the scribe member on a first start point on the insulating substrate under a predetermined load, and scribing the insulating substrate from the first start point to a first end point in a first direction, thereby forming a first scribe line; and
a step of lowering the scribe member, pressing the scribe member on a second start point, which is spaced apart from the first scribe line, under a predetermined load, and scribing the insulating substrate from the second start point to a second end point in a second direction that intersects the first direction, thereby forming a second scribe line that is spaced apart from the first scribe line.

7. The method of manufacturing a display device, according to claim 6, further comprising:
a step of moving the scribe member beyond the first scribe line, lowering the scribe member on a third start point that is collinear with the second scribe line, pressing the scribe member on the third start point under a predetermined load, and scribing the insulating substrate from the third start point to a third end point in the second direction, thereby forming a third scribe line.

8. The method of manufacturing a display device, according to claim 6, further comprising:
a step of moving the scribe member beyond the first scribe line, lowering the scribe member on a third start point that is non-collinear with the second scribe line, pressing the scribe member on the third start point under a predetermined load, and scribing the insulating substrate from the third start point to a third end point in the second direction, thereby forming a third scribe line that is parallel to the second scribe line and is spaced apart from the first scribe line.

9. The method of manufacturing a display device, according to claim 6, wherein the scribe member is shifted to a predetermined start point by relative movement in association with movement of the insulating substrate.

10. A method of manufacturing a display device comprising:
a step of forming an effective display section, which forms the display device, on an insulating substrate; and
a step of forming a scribe line in a direction that intersects an edge of the insulating substrate,
wherein the effective display section has one side that agrees with the edge of the insulating substrate, and
the scribe line is spaced apart from the edge of the insulating substrate.
